(19) United States
(12) Patent Application Publication
(10) Pub. No.: US 2026/0036605 A1
(43) Pub. Date: Feb. 5, 2026

(54) ELECTRICALLY CONDUCTIVE CONTACT PIN AND INSPECTION APPARATUS COMPRISING THE SAME

(71) Applicant: POINT ENGINEERING CO., LTD., Asan-si (KR)

(72) Inventors: Bum Mo AHN, Suwon-si (KR); Seung Ho PARK, Hwaseong-si (KR); Chang Hee HONG, Yongin-si (KR)

(73) Assignee: POINT ENGINEERING CO., LTD., Asan-si (KR)

(21) Appl. No.: 19/287,837

(22) Filed: Aug. 1, 2025

(30) Foreign Application Priority Data
Aug. 5, 2024 (KR) 10-2024-0104131

(51) Int. Cl. G01R 1/067; G01R 1/073

(52) U.S. Cl. CPC G01R 1/06716; G01R 1/07314

(57) ABSTRACT

The present invention provides an inspection apparatus comprising an electrically conductive contact pin having one end contacting a connection pad of an inspection apparatus and another end contacting a connection pad of an inspection object to inspect the inspection object, and a guide plate having a guide hole into which the electrically conductive contact pin is inserted, wherein the electrically conductive contact pin comprises a body portion including a first metal layer and a second metal layer made of a metal having relatively higher electrical conductivity than the first metal layer, alternately stacked in a thickness direction, and an elastic portion including a plurality of unit elastic bodies spaced apart from each other in the thickness direction at one end, which can be easily elastically deformed by close contact and pressing by a connection object.

### CROSS-REFERENCE TO RELATED APPLICATIONS

The present application claims priority to Korean Patent Application No. 10-2024-0104131, filed Aug. 5, 2024, the entire contents of which is incorporated herein for all purposes by this reference.

### TECHNICAL FIELD

The present invention relates to an electrically conductive contact pin and an inspection apparatus comprising the same.

### BACKGROUND

FIG. 1 is a diagram schematically illustrating a probe card 1 according to the prior art.

Generally, the probe card 1 is configured to include a circuit board 2, a space transformer 3 provided on the lower side of the circuit board 2, and a probe head 7 provided on the lower side of the space transformer 3.

The probe head 7 includes a plurality of probe pins 7 and guide plates 5 and 6 having guide holes into which the probe pins 7 are inserted. The probe head 7 includes an upper guide plate 5 and a lower guide plate 6, and the upper guide plate 5 and the lower guide plate 6 are fixedly installed through spacers. The probe pins 7 are structured to elastically deform between the upper guide plate 5 and the lower guide plate 6, and by adopting such probe pins 7, a vertical probe card 1 is configured.

The electrical characteristic test of a semiconductor device is performed by bringing a semiconductor wafer W close to the probe card 1, which has a plurality of probe pins 7, and contacting each probe pin 7 with a corresponding electrode pad WP on the inspection object (semiconductor wafer W).

Meanwhile, in recent inspections of LSI chips, there are cases where high-frequency current flows. However, if a gap occurs between the probe pin 7 and the space transformer 3 or between the probe pin 7 and the inspection object, sparks are generated, and the sparks cause damage to the probe pin 7 and the connection object.

To solve such problems, Korean Unexamined Patent Publication No. 10-2023-0049214 (hereinafter referred to as “prior invention”) proposes a probe pin having an elastic portion.

The prior invention discloses a structure of a probe pin having an elastic portion configured by alternately stacking first and second metal layers of different materials in the thickness direction at one end. By providing such an elastic portion at one end, the probe pin is pressed and compressed by the connection object, enabling the one end to always remain in contact with the connection object.

However, in the case of providing an elastic portion configured by alternately stacking the first and second metal layers as in the prior invention, there is an advantageous aspect of improving the electrical conductivity of the elastic portion. However, from the perspective of elastic deformation, the elastic deformation of the one end of the probe pin is difficult, and the elastic restoring force is reduced. As a result, if the one end of the probe pin, which is elastically deformed by the connection object, does not easily undergo elastic deformation, there is a problem of increasing the stress applied to the probe pin itself.

### PRIOR ART DOCUMENTS

### Patent Documents

(Patent Document 1) Korean Patent Publication No. 10-2023-0049214

### SUMMARY

The present invention has been devised to solve the aforementioned problems, and its purpose is to provide an electrically conductive contact pin, which is equipped with an elastic portion at one end that can be easily elastically deformed to minimize stress applied to itself, and an inspection apparatus comprising the same.

To achieve the object of the present invention, an inspection apparatus according to the present invention comprises: an electrically conductive contact pin having one end contacting a connection pad of an inspection apparatus and another end contacting a connection pad of an inspection object to inspect the inspection object; and a guide plate having a guide hole into which the electrically conductive contact pin is inserted, wherein the electrically conductive contact pin comprises: a body portion comprising a first metal layer and a second metal layer made of a metal having relatively higher electrical conductivity than the first metal layer, alternately stacked in a thickness direction; and an elastic portion enabling the one end to be pressed and compressed by the connection pad of the inspection apparatus when the guide plate is installed on the inspection apparatus side, thereby maintaining the one end in constant contact with the connection pad of the inspection apparatus, wherein the elastic portion consists of a plurality of unit elastic bodies spaced apart from each other in the thickness direction.

In addition, the unit elastic body consists of the first metal layer.

In addition, a thickness direction dimension constituting a spacing distance of the unit elastic bodies is the same as a thickness direction dimension of the second metal layer of the body portion.

In addition, a surface of the unit elastic body is plated with a surface metal.

In addition, the unit elastic body is a closed-type elastic body comprising a pillar portion having an internal space penetrating in the thickness direction and entirely surrounding the internal space.

In addition, the unit elastic body is an open-type elastic body comprising a pillar portion having an internal space penetrating in the thickness direction and having an upper portion or side portion cut to partially surround the internal space.

Meanwhile, an electrically conductive contact pin according to another aspect of the present invention, in an electrically conductive contact pin having one end contacting a connection pad of an inspection apparatus and another end contacting a connection pad of an inspection object to inspect the inspection object, comprises: a body portion comprising a first metal layer and a second metal layer made of a metal having relatively higher electrical conductivity than the first metal layer, alternately stacked in a thickness direction; and an elastic portion provided at the one end to enable the one end to be pressed and compressed by the connection pad of the inspection apparatus when a guide plate is installed on the inspection apparatus side, thereby maintaining the one end in constant contact with the connection pad of the inspection apparatus, wherein the elastic portion consists of a plurality of unit elastic bodies spaced apart from each other in the thickness direction.

In addition, the one end consists of a closed-type elastic body having an internal space.

In addition, the one end consists of a closed-type unit elastic body having an internal space and a contact plane portion configured as a plane on top of the closed-type unit elastic body.

In addition, the one end consists of the unit elastic body having an internal space with an upper portion cut to provide at least two contact portions.

In addition, the one end consists of the unit elastic body having an internal space with an upper portion cut to provide at least two contact portions and a contact plane portion configured as a plane on top of the unit elastic body.

In addition, the one end consists of the unit elastic body having an internal space with a side portion cut.

In addition, the one end comprises a catching jaw formed larger than a size of the guide hole to prevent the unit elastic body from passing through the guide hole of the guide plate, wherein the unit elastic body is positioned above the catching jaw.

The present invention provides an electrically conductive contact pin comprising an elastic portion that includes a plurality of unit elastic bodies spaced apart at one end, which can be easily elastically deformed by close contact and pressing by a connection object, and an inspection apparatus comprising the same.

### BRIEF DESCRIPTION OF DRAWINGS

The above and other features of embodiments of the disclosure will become apparent by describing in detail embodiments thereof with reference to the accompanying drawings.

FIG. 1 is a diagram schematically illustrating a probe card according to the prior art.

FIG. 2 is a diagram illustrating a probe head provided with an electrically conductive contact pin according to a preferred first embodiment of the present invention.

FIGS. 3A to 3C are diagrams illustrating an electrically conductive contact pin according to a preferred first embodiment of the present invention.

FIGS. 4A to 5C are diagrams illustrating examples of deformation of the elastic portion of the electrically conductive contact pin according to a preferred first embodiment of the present invention.

FIGS. 6A to 6C are diagrams illustrating an electrically conductive contact pin according to a preferred second embodiment of the present invention.

FIGS. 7A to 7C are diagrams illustrating an example of deformation of the elastic portion of the electrically conductive contact pin according to a preferred second embodiment of the present invention.

FIGS. 8A to 8C are diagrams illustrating an electrically conductive contact pin according to a preferred third embodiment of the present invention.

FIGS. 9A to 9C are diagrams illustrating an electrically conductive contact pin according to a preferred fourth embodiment of the present invention.

FIG. 10 is a diagram illustrating an electrically conductive contact pin according to a preferred fifth embodiment of the present invention.

FIGS. 11A to 11C are diagrams illustrating an electrically conductive contact pin according to a preferred sixth embodiment of the present invention.

FIGS. 12A to 12D are diagrams for explaining a method of manufacturing an electrically conductive contact pin according to a preferred embodiment of the present invention.

FIG. 13 is a diagram illustrating a side view of an electrically conductive contact pin according to a preferred embodiment of the present invention.

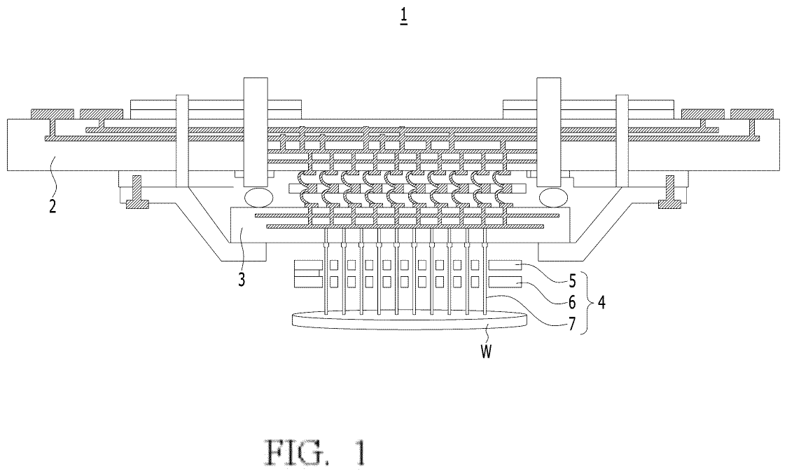

### DETAILED DESCRIPTION OF THE EMBODIMENTS

The following content merely exemplifies the principles of the invention. Therefore, those skilled in the art can implement the principles of the invention and devise various devices included in the concept and scope of the invention, even if they are not explicitly described or illustrated in this specification. Furthermore, all conditional terms and embodiments listed in this specification are, in principle, explicitly intended only for the purpose of understanding the concept of the invention and should not be understood as being limited to the specifically listed embodiments and conditions.

The aforementioned objectives, features, and advantages will become more apparent through the following detailed description in connection with the accompanying drawings, thereby enabling those skilled in the art to easily implement the technical idea of the invention.

The embodiments described in this specification will be explained with reference to ideal exemplary cross-sectional and/or perspective views of the invention. The thicknesses of the films and regions shown in these drawings are exaggerated for effective explanation of the technical content. The shapes illustrated in the exemplary drawings may be modified due to manufacturing techniques and/or tolerances. Therefore, the embodiments of the invention are not limited to the specific forms shown but also include variations in shape generated by the manufacturing process. The technical terms used in this specification are merely used to describe specific embodiments and are not intended to limit the invention. Singular expressions include plural expressions unless the context clearly indicates otherwise. In this specification, terms such as “comprising” or “having” are intended to specify the presence of features, numbers, steps, operations, components, parts, or combinations thereof described in this specification, and should not be understood as precluding the possibility of the presence or addition of one or more other features, numbers, steps, operations, components, parts, or combinations thereof.

Hereinafter, the preferred embodiments of the present invention will be described in detail with reference to the accompanying drawings. In describing various embodiments below, components performing the same function will be given the same names and reference numbers for convenience, even if the embodiments differ. Furthermore, the configuration and operation already described in other embodiments will be omitted for convenience.

The electrically conductive contact pins according to the preferred embodiments of the present invention may be conductive contact pins used in inspection apparatuses for determining defects in inspection objects by applying electricity and physically and electrically contacting the inspection objects to transmit electrical signals. The inspection apparatus may be an inspection apparatus used in semiconductor manufacturing processes, such as a probe card or a test socket. The electrically conductive contact pins may be probe pins provided in a probe card for inspecting semiconductor chips or socket pins provided in a test socket for inspecting packaged semiconductor packages.

Hereinafter, the first to sixth embodiments will be described separately, but embodiments combining the configurations of each embodiment are also included in the preferred embodiments of the present invention.

In the following description, the width direction of the electrically conductive contact pin is the ±x direction indicated in the drawings, the length direction is the ±y direction, and the thickness direction is the ±z direction. The electrically conductive contact pin has an overall length dimension (L) in the length direction (±y direction), an overall thickness dimension (H) in the thickness direction (±z direction) perpendicular to the length direction, and an overall width dimension (W) in the width direction (±x direction) perpendicular to the length direction.

### First Embodiment

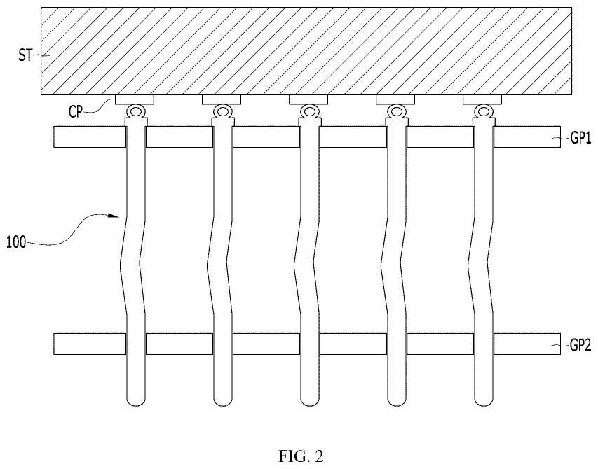

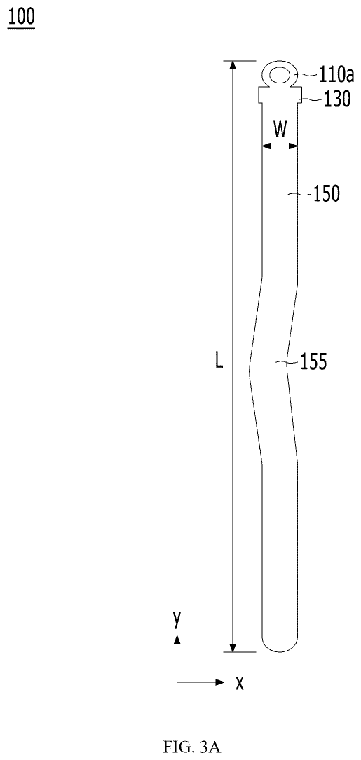

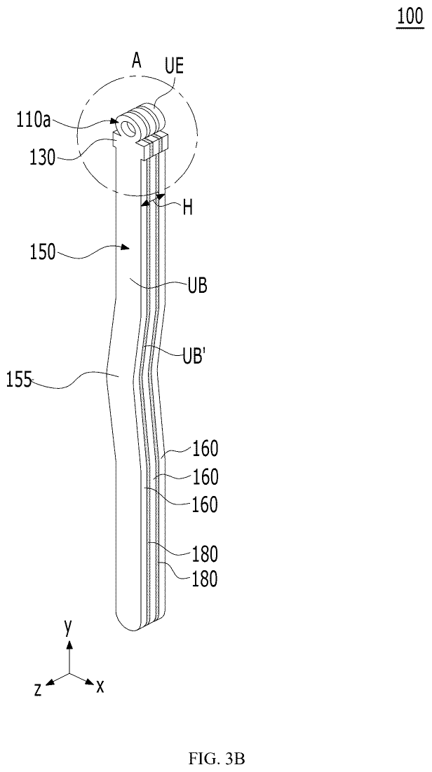

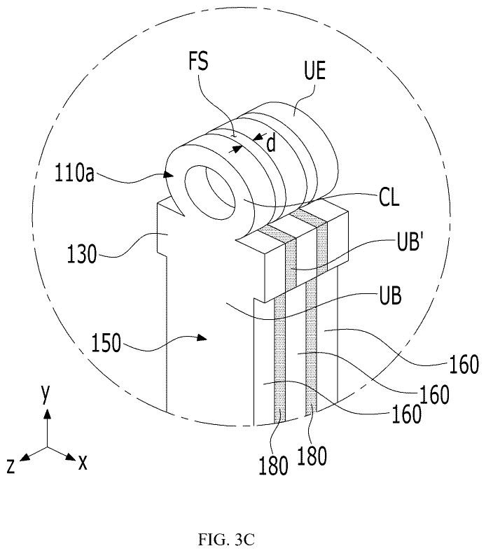

Hereinafter, the electrically conductive contact pin 100 according to the preferred first embodiment of the present invention will be described with reference to FIGS. 2, 3A, 3B, and 3C.

FIG. 2 is a view illustrating a probe head equipped with the electrically conductive contact pin 100 according to the preferred first embodiment of the present invention, and FIGS. 3A to 3C are views illustrating the electrically conductive contact pin 100 according to the preferred first embodiment of the present invention.

The probe card according to the preferred embodiment of the present invention is used in an inspection process for inspecting chips fabricated on a wafer during a semiconductor manufacturing process and is capable of responding to fine pitches. The probe card according to the preferred embodiment of the present invention is more useful for inspecting non-memory semiconductor chips such as microprocessors, microcontrollers, and ASICs.

The probe card according to the preferred embodiment of the present invention comprises a space transformer ST having connection pads CP; a guide plate GP1, GP2 provided below the space transformer ST and spaced apart from the space transformer ST; and electrically conductive contact pins 100 inserted into holes of the guide plate GP1, GP2 and functioning as probe pins.

The guide plate comprises an upper guide plate GP1 and a lower guide plate GP2 spaced apart from the upper guide plate GP1. The electrically conductive contact pin 100 is inserted into the guide holes of the upper guide plate GP1 and the lower guide plate GP2. The electrically conductive contact pin 100 is elastically deformed in the width direction (x direction) between the upper guide plate GP1 and the lower guide plate GP2.

The pitch spacing between the electrically conductive contact pins 100 installed and arranged in the guide plate GP1, GP2 may be 50 μm to 150 μm, the left and right width of the electrically conductive contact pin 100 may be 40 μm to 200 μm, and the thickness of the electrically conductive contact pin 100 may be 40 μm to 200 μm.

One end of the electrically conductive contact pin 100 is connected to the connection pad CP of the inspection apparatus (space transformer ST), and the other end of the electrically conductive contact pin 100 is connected to the connection pad of the inspection object. Here, the inspection object may be a semiconductor device.

The electrically conductive contact pin 100 has a length L in the longitudinal direction, a width W in the transverse direction, and a thickness H in the direction perpendicular to the longitudinal and transverse directions. The thickness H of the one end including the elastic portion 110a is the same as the thickness H of the rest of the electrically conductive contact pin 100 excluding the elastic portion 110a.

The electrically conductive contact pin 100 comprises a body portion 150. The body portion 150 allows the electrically conductive contact pin 100 to be elastically deformed in the width direction (x direction) and performs the function of forming a current path between the connection objects (inspection apparatus and inspection object).

The body portion 150 comprises at least one bending portion 155. Through the configuration of the bending portion 155, the body portion 150 can be deformed in the width direction (x direction).

The body portion 150 is provided in a form in which a first metal layer 160 and a second metal layer 180, made of a metal having relatively higher electrical conductivity than the first metal layer 160, are alternately stacked in the thickness direction (±z direction).

The first metal layer 160 is a metal having relatively higher wear resistance or rigidity than the second metal layer 180 and is preferably formed of a metal selected from rhodium (Rd), platinum (Pt), iridium (Ir), palladium (Pd), nickel (Ni), manganese (Mn), tungsten (W), phosphorus (Ph), or alloys thereof, or palladium-cobalt (PdCo) alloy, palladium-nickel (PdNi) alloy, nickel-phosphorus (NiPh) alloy, nickel-manganese (NiMn), nickel-cobalt (NiCo), or nickel-tungsten (NiW) alloy. The second metal layer 180 is a metal having relatively higher electrical conductivity than the first metal layer 160 and is preferably formed of a metal selected from copper (Cu), silver (Ag), gold (Au), or alloys thereof.

The first metal layer 160 is provided on the lower and upper surfaces of the electrically conductive contact pin 100 in the thickness direction (±z direction), and the second metal layer 180 is provided between the first metal layers 160. For example, the electrically conductive contact pin 100 is alternately stacked in the order of the first metal layer 160, the second metal layer 180, and the first metal layer 160, and the number of stacked layers may be three or more.

The body portion 150 is formed to a size that can pass through the guide holes of the guide plate GP1, GP2. The body portion 150 has a rectangular cross-sectional shape, and the guide holes of the guide plate GP1, GP2 are also configured in a rectangular cross-sectional shape. Through this, after the electrically conductive contact pin 100 is inserted into the guide hole, the electrically conductive contact pin 100 does not rotate within the guide hole, thereby maintaining the bending direction of the plurality of electrically conductive contact pins 100 consistently.

The electrically conductive contact pin 100 comprises an elastic portion 110a at one end between the guide plate (specifically, the upper guide plate GP1 and the connection pad CP of the inspection apparatus.

Specifically, the electrically conductive contact pin 100 comprises a body portion 150 at the other end and an elastic portion 110a on one side of the body portion 150, thereby having an elastic portion 110a at one end.

Due to manufacturing process errors, there are length differences among the plurality of electrically conductive contact pins 100. Additionally, since the flatness of the guide plate GP1, GP2 and the space transformer ST also slightly differs, there are height differences among the connection pads CP. Therefore, to ensure good electrical and mechanical contact for all electrically conductive contact pins 100, the electrically conductive contact pins 100 must be installed while being pressed toward the inspection apparatus. When the guide plate GP1, GP2 with the electrically conductive contact pins 100 installed is mounted on the inspection apparatus side, the elastic portion 110a is closely adhered to and pressed against the connection pad CP of the inspection apparatus, undergoing compressive deformation. Through this, the ends of all electrically conductive contact pins 100 are always maintained in contact with the connection pad CP of the inspection apparatus, thereby preventing the occurrence of sparks.

The elastic portion 110a comprises a plurality of unit elastic bodies UE spaced apart from each other in the thickness direction. Accordingly, the one end of the electrically conductive contact pin 100 is provided with an elastic portion 110a composed of a plurality of unit elastic bodies UE.

The unit elastic body UE is composed of the first metal layer 160. Specifically, the first metal layer 160 constituting the unit elastic body UE is made of the same material as the first metal layer 160 constituting the body portion 150. Therefore, the first metal layer 160 is a metal having relatively higher wear resistance or rigidity, and is preferably formed of a metal selected from rhodium (Rd), platinum (Pt), iridium (Ir), palladium (Pd), nickel (Ni), manganese (Mn), tungsten (W), phosphorus (Ph), or alloys thereof, or palladium-cobalt (PdCo) alloy, palladium-nickel (PdNi) alloy, nickel-phosphorus (NiPh) alloy, nickel-manganese (NiMn), nickel-cobalt (NiCo), or nickel-tungsten (NiW) alloy.

The electrically conductive contact pin 100 comprises an elastic portion 110a through a portion extending from one end of the body portion 150. Accordingly, the elastic portion 110a is continuously connected to and integrally provided with the body portion 150. The elastic portion 110a comprises a plurality of unit elastic bodies UE spaced apart from each other in the thickness direction (±z direction). Therefore, the elastic portion 110a is continuously connected to and integrally provided with the body portion 150 through a portion extending from one end of the part of the body portion 150 composed of the first metal layer 160.

More specifically, the unit elastic body UE is provided continuously and integrally connected in the length direction (±y direction) to the first unit body UB composed of the first metal layer 160 constituting the body portion 150 through a portion extending from one end of the first unit body UB.

The body portion 150 is configured by alternately stacking the first and second metal layers 160, 180 in the thickness direction (±z direction). In other words, the body portion 150 is configured by alternately stacking the first unit body UB composed of the first metal layer 160 and the second unit body UB′ composed of the second metal layer 180 in the thickness direction (±z direction). At this time, the unit elastic body UE is provided through a portion extending from one end of the first unit body UB composed of the first metal layer 160. The body portion 150 comprises a plurality of first unit bodies UB. Accordingly, a plurality of unit elastic bodies UE composed of the first metal layer 160 are provided continuously and integrally connected to the body portion 150 through portions extending from one end of each first unit body UB.

Each first unit body UB composed of the first metal layer 160 of the body portion 150 is provided at a spacing distance d corresponding to the thickness direction (±z direction) dimension of the second unit body UB′ composed of the second metal layer 180. Accordingly, each unit elastic body UE provided through a portion extending from one end of each first unit body UB composed of the first metal layer 160 of the body portion 150 has a spacing distance d corresponding to the thickness direction (±z direction) dimension of the second metal layer 180 of the body portion 150. In other words, the thickness direction (±z direction) dimension constituting the spacing distance d of each unit elastic body UE is the same as the thickness direction (±z direction) dimension of the second metal layer 180 of the body portion 150 (the thickness direction (±z direction) dimension of the second unit body UB′ composed of the second metal layer 180).

The electrically conductive contact pin 100, by comprising an elastic portion 110a composed of a plurality of unit elastic bodies UE spaced apart from each other, is easily elastically deformed when pressed against and adhered to an object (e.g., connection pad CP). The elastic portion 110a has a relatively smaller thickness direction (±z direction) dimension than the body portion 150 due to the plurality of unit elastic bodies UE provided at a spacing distance d. Furthermore, the plurality of unit elastic bodies UE are composed of the first metal layer 160, which is made of the same material as the first metal layer 160 constituting the body portion 150, and thus have high elastic recovery force.

Accordingly, the electrically conductive contact pin 100 facilitates elastic deformation at the one end provided with the elastic portion 110a.

The surface of the elastic portion 110a provided at one end of the electrically conductive contact pin 100 is plated with a surface metal. Accordingly, the electrically conductive contact pin 100 can effectively respond to high-frequency characteristic inspections.

More specifically, the surfaces of the plurality of unit elastic bodies UE are plated with a surface metal having high electrical conductivity. The surface metal is a metal with relatively higher electrical conductivity than the unit elastic body UE and may be gold (Au), silver (Ag), copper (Cu), or the like, and preferably gold (Au). The surface metal is formed through a plating process.

By comprising an elastic portion 110a plated with a surface metal (preferably gold (Au)) at one end, the electrically conductive contact pin 100 can minimize contact resistance and improve the efficiency of signal transmission. Particularly, since high-frequency signals flow along the surface of the conductor, plating with a surface metal (preferably gold (Au)) with high surface conductivity can reduce signal loss.

In high-frequency signals, the skin effect occurs, causing current to flow along the surface of the conductor. The surface metal reduces such surface resistance and minimizes signal distortion. The electrically conductive contact pin 100, by plating the surface of the elastic portion 110a at one end with a surface metal, can perform more accurate high-frequency characteristic inspections.

Moreover, in high-frequency characteristic inspections, it is important to transmit signals accurately without distortion. By plating the surface of the elastic portion 110a at one end with a surface metal, the electrically conductive contact pin 100 can minimize interference with noise, maintain the purity of the signal, and improve the accuracy of high-frequency characteristic inspections.

The electrically conductive contact pin 100, by comprising an elastic portion 110a composed of a plurality of unit elastic bodies UE at one end, can implement multi-contact with the connection pad CP.

Specifically, the plurality of unit elastic bodies UE are provided spaced apart in the thickness direction (±z direction) and behave separately. Accordingly, each unit elastic body UE can individually contact the lower surface of the connection pad CP when the connection pad CP is pressed and adhered.

By comprising a plurality of unit elastic bodies UE that behave independently, the electrically conductive contact pin 100 can maintain connection with the connection pad CP through the remaining unit elastic bodies UE, even if any one of the unit elastic bodies UE fails to contact the connection pad CP. Therefore, by comprising an elastic portion 110a composed of a plurality of unit elastic bodies UE at one end, the electrically conductive contact pin 100 can improve connection reliability.

By comprising an elastic portion 110a composed of a plurality of unit elastic bodies UE spaced apart from each other at one end, the electrically conductive contact pin 100 can provide a foreign substance drop space FS at that end.

Specifically, the spacing distance d between each unit elastic body UE forms a fine space at one end of the electrically conductive contact pin 100. The fine space formed by the spacing distance d between each unit elastic body UE provides a foreign substance drop space FS. The one end of the electrically conductive contact pin 100 is preferably located on the connection pad CP side. Therefore, when the connection pad CP is pressed and adhered, foreign substances from the connection pad CP may transfer to the surface of the one end of the electrically conductive contact pin 100. At this time, the foreign substances can fall into the foreign substance drop space FS formed at one end of the electrically conductive contact pin 100 by the spacing distance (d) between each unit elastic body UE.

Unlike the electrically conductive contact pin 100 of the present invention, if there is no foreign substance drop space FS formed at one end of the electrically conductive contact pin 100 by the spacing distance d between each unit elastic body UE, the foreign substances transferred from the connection pad CP to the surface of one end of the electrically conductive contact pin 100 will remain on the surface. If foreign substances remain on the surface of the one end of the electrically conductive contact pin 100 that contacts the connection pad CP, the foreign substances may act as resistance elements, causing a problem of reduced connection reliability.

However, the electrically conductive contact pin 100 according to the first embodiment of the present invention comprises an elastic portion 110a composed of a plurality of unit elastic bodies UE spaced apart from each other at one end that contacts the connection pad CP. As a result, the electrically conductive contact pin 100 can provide a foreign substance drop space FS at one end. The foreign substances transferred from the connection pad CP fall into the foreign substance drop space FS provided by the spacing distance d between each unit elastic body UE. Accordingly, the electrically conductive contact pin 100 can prevent foreign substances from remaining on the surface of one end. As a result, the electrically conductive contact pin 100 prevents the problem of reduced connection reliability caused by foreign substances remaining on the surface.

The plurality of unit elastic bodies UE constituting the elastic portion 110a are closed-type elastic bodies having an internal space penetrating in the thickness direction and a pillar portion CL entirely surrounding the internal space. The shapes of each unit elastic body UE are identical. The closed-type elastic body is a structure that elastically deforms when there is contact pressure with the connection object.

The thickness direction (±z direction) cross-sectional shape of the unit elastic body UE is a circular ring or an elliptical ring shape.

In the assembly process of the probe card comprising the electrically conductive contact pin 100 according to the preferred first embodiment of the present invention, the electrically conductive contact pin 100 is first inserted into the guide plate GP1, GP2 to assemble the probe head. At this time, since the body portion 150 of the electrically conductive contact pin 100 is smaller than the guide hole, it passes through the guide hole, and the catching jaw 130 catches on the upper surface of the upper guide plate GP1, preventing the electrically conductive contact pin 100 from falling out of the guide plate GP1, GP2.

The catching jaw 130 is included at one end of the electrically conductive contact pin 100 and is provided below the elastic portion 110a. More specifically, the unit elastic body UE is located above the catching jaw 130. Accordingly, the catching jaw 130 is provided between the elastic portion 110a and the body portion 150.

The catching jaw 130 is composed of the first and second metal layers 160, 180 of the same material as the first and second metal layers 160, 180 constituting the body portion 150. The first and second metal layers 160, 180 constituting the catching jaw 130 are alternately stacked in the thickness direction (±z direction). At this time, the unit elastic body UE provided above the catching jaw 130 is located at a position corresponding to the first metal layer 160 of the catching jaw 130.

The catching jaw 130 is continuously connected to and integrally provided with the elastic portion 110a and the body portion 150 in the length direction (±y direction) between the elastic portion 110a and the body portion 150.

The catching jaw 130 is formed larger than the size of the guide hole to prevent the unit elastic body UE from passing through the guide hole of the upper guide plate GP1. Through this, the electrically conductive contact pin 100 does not fall out of the guide plate GP1, GP2.

Next, the probe head is fixed to the space transformer ST side. At this time, the elastic portion 110a of the electrically conductive contact pin 100 contacts the connection pad CP of the space transformer ST and undergoes elastic deformation. As the elastic portion 110a is elastically supported while in contact with the connection object, the ends of the plurality of electrically conductive contact pins 100 always maintain contact with the connection pad of the space transformer ST. In this state, the inspection object is positioned at the lower end of the electrically conductive contact pin 100 to inspect the inspection object.

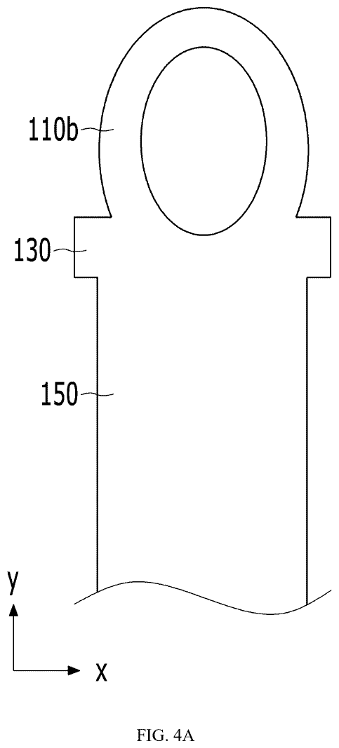

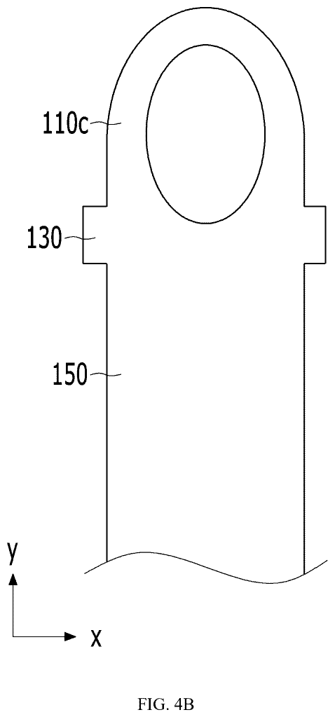

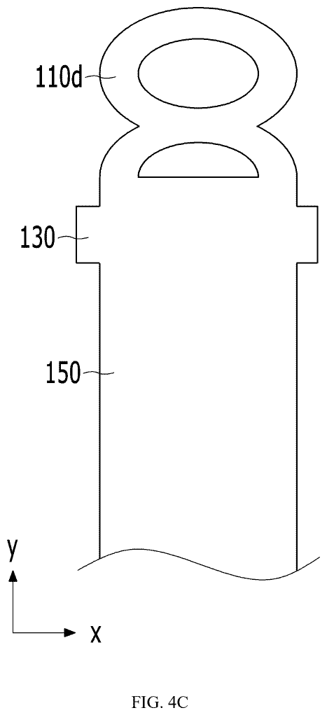

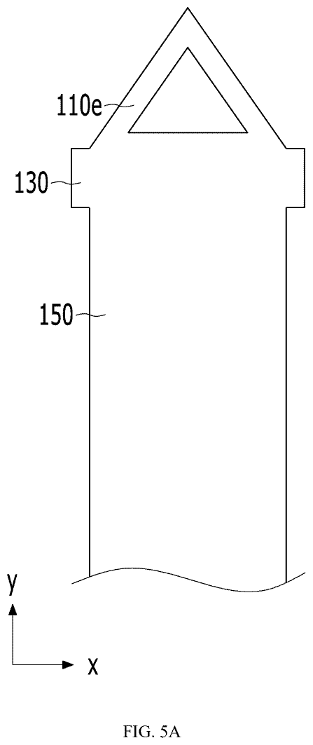

FIGS. 4A to 4C and FIGS. 5A to 5C are views illustrating variations of the elastic portion 110a of the electrically conductive contact pin 100 according to the preferred first embodiment of the present invention.

Referring to FIG. 4A, the elastic portion 110b shown in FIG. 4A differs from the configuration of the elastic portion 110a shown in FIG. 3 in that at least a part of the internal space of the elastic portion 110b is provided at a position overlapping with the position of the catching jaw 130. Through this, the stress concentration phenomenon can be prevented, and the effect of preventing damage due to deformation of the elastic portion 110d can be achieved.

Referring to FIG. 4B, the elastic portion 110c shown in FIG. 4B differs from the configuration of the elastic portion 110a shown in FIG. 3 in that at least a part of the internal space of the elastic portion 110c is provided at a position overlapping with the position of the catching jaw 130 and in that the elastic portion 110c is provided with a thickened side portion. Through this, the stress concentration phenomenon can be prevented, and the effect of preventing damage due to deformation of the elastic portion 110d can be achieved.

Referring to FIG. 4C, the elastic portion 110d shown in FIG. 4C differs from the configuration of the elastic portion 110a shown in FIG. 3 in that it is composed of a plurality of closed-type pillar portions. The cross-sectional shapes of the plurality of closed-type pillar portions may be identical or different. Through this, the stress concentration phenomenon can be prevented, and the effect of preventing damage due to deformation of the elastic portion 110d can be achieved.

Referring to FIG. 5A, the elastic portion 110e shown in FIG. 5A differs from the configuration of the elastic portion 110a shown in FIG. 3 in that the internal space is triangular, and the closed-type pillar portion has a triangular shape.

Referring to FIG. 5B, the elastic portion 110f shown in FIG. 5B differs from the configuration of the elastic portion 110a shown in FIG. 3 in that the internal space is rhombic, and the closed-type pillar portion has a rhombic shape.

Referring to FIG. 5C, the elastic portion 110g shown in FIG. 5C differs from the configuration of the elastic portion 110a shown in FIG. 3 in that the internal space is semi-circular, and the closed-type pillar portion has a semi-circular shape.

The variations of the elastic portion 110a according to the first embodiment are not limited to the elastic portions 110b, 110c, 110d, 110e, 110f, and 110g described above, and any configuration of an elastic portion comprising a plurality of unit elastic bodies UE composed of closed-type elastic bodies with internal spaces is included.

Meanwhile, in the above description, the one end provided with the elastic portion 110a is described as being located on the inspection apparatus side, but as a variation, a configuration in which the elastic portion 110a is located on the inspection object side is also possible, as well as a configuration in which the elastic portion 110a is located on both the inspection apparatus side and the inspection object side.

Additionally, although a probe card is illustrated in FIG. 2, the electrically conductive contact pin 100 according to the preferred first embodiment of the present invention may be an electrically conductive contact pin 100 provided not only in a probe card but also in a test socket for inspecting packaged semiconductor packages.

### Second Embodiment

Next, the second embodiment according to the present invention will be described. However, the embodiments described below will focus on characteristic components compared to the first embodiment, and descriptions of components identical or similar to those in the first embodiment will be omitted as much as possible.

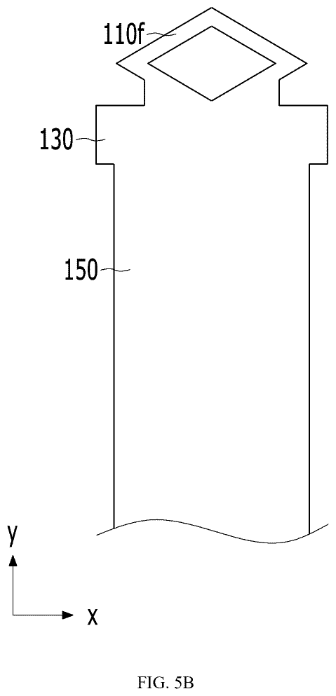

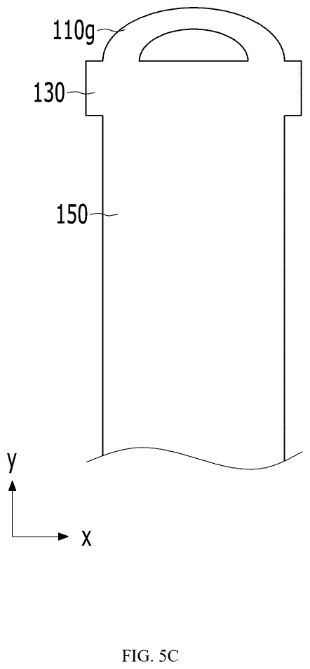

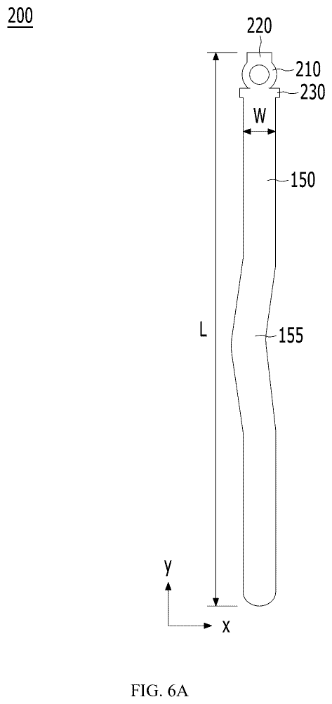

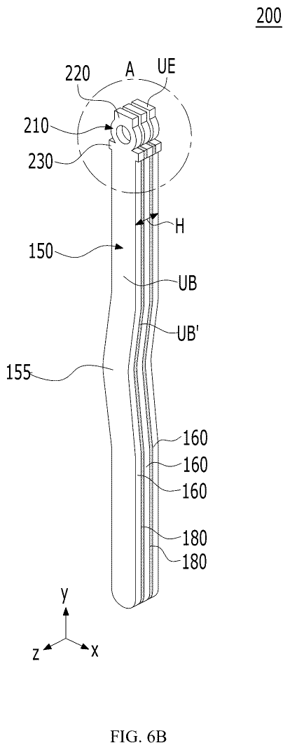

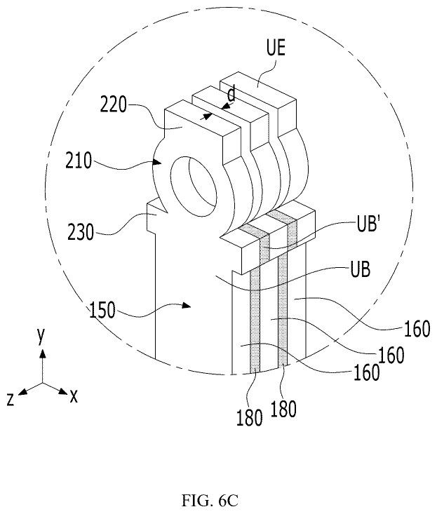

Hereinafter, the electrically conductive contact pin 200 according to the preferred second embodiment of the present invention will be described with reference to FIGS. 6A and 6B. FIG. 6A is a view illustrating the electrically conductive contact pin 200 according to the preferred second embodiment of the present invention, and FIG. 6B is an enlarged view of a part of FIG. 6A.

The electrically conductive contact pin 200 according to the preferred second embodiment of the present invention differs from the configuration of the electrically conductive contact pin 100 according to the first embodiment, which does not include a contact plane portion 220, in that the one end comprises an elastic portion 210 composed of a plurality of unit elastic bodies UE formed of closed-type elastic bodies with internal spaces and a contact plane portion 220 configured as a plane on top of the elastic portion 210.

Each unit elastic body UE is provided at a spacing distance d.

The contact plane portion 220 provided on top of each unit elastic body UE composed of closed-type elastic bodies is the part that contacts the connection pad CP of the inspection apparatus, which is the connection object. The contact plane portion 220 is configured as a plane to improve connection reliability.

A catching jaw 230 is provided between the elastic portion 210 and the body portion 150.

The elastic portion 210 according to the second embodiment, comprising a plurality of unit elastic bodies UE formed of closed-type elastic bodies, may be configured as the elastic portions 110a, 110b, 110c, 110d, 110e, 110f, 110g described in the first embodiment.

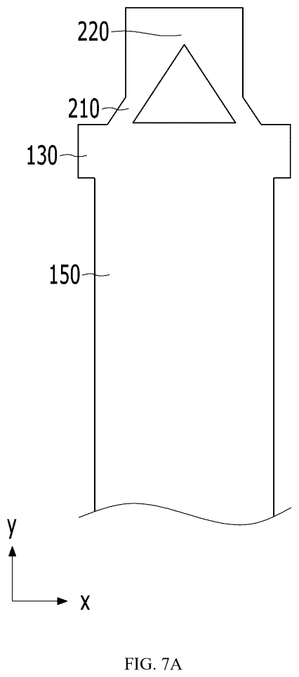

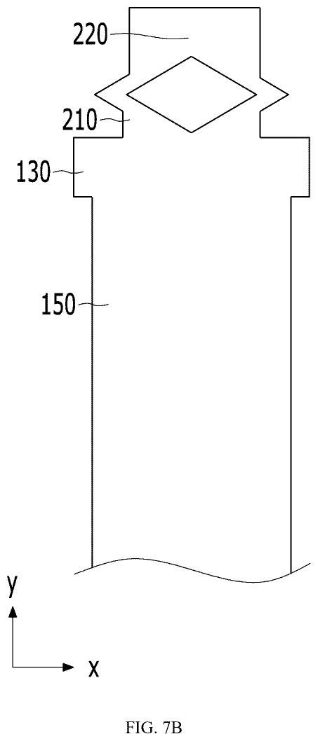

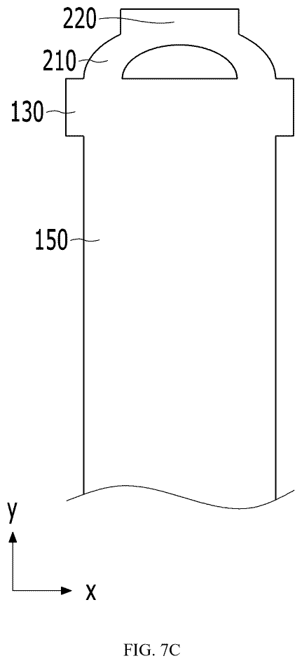

For example, FIGS. 7A to 7C are views illustrating variations of the one end of the electrically conductive contact pin 200 according to the preferred second embodiment of the present invention. The one end of the electrically conductive contact pin 200 shown in FIG. 7A has a structure in which the contact plane portion 220 is provided on top of the elastic portion 110e shown in FIG. 5A. The one end of the electrically conductive contact pin 200 shown in FIG. 7B has a structure in which the contact plane portion 220 is provided on top of the elastic portion 110f shown in FIG. 5B. The one end of the electrically conductive contact pin 200 shown in FIG. 7C has a structure in which the contact plane portion 220 is provided on top of the elastic portion 110g shown in FIG. 5C.

The contact plane portion 220 is provided on top of each unit elastic body UE constituting the elastic portion 110g and is composed of the first metal layer 160. Accordingly, the contact plane portions 220 provided on top of each unit elastic body UE are spaced apart from each other. The spacing distance between the contact plane portions 220 is the same as the spacing distance between each unit elastic body UE. The electrically conductive contact pin 100 comprises the contact plane portion 220 provided on top of the elastic portion 110a with the same spacing distance as the spacing distance between each unit elastic body UE constituting the elastic portion 110a and is composed of the first metal layer 160 constituting the unit elastic body UE. Accordingly, when the connection object contacts the contact plane portion 220, the elastic portion 110a can be easily elastically deformed. The contact plane portion 220 is provided on top of each unit elastic body UE and is continuously connected in the length direction (±y direction) to each unit elastic body UE and integrally provided.

### Third Embodiment

Next, the third embodiment according to the present invention will be described. However, the embodiments described below will focus on characteristic components compared to the first embodiment, and descriptions of components identical or similar to those in the first embodiment will be omitted as much as possible.

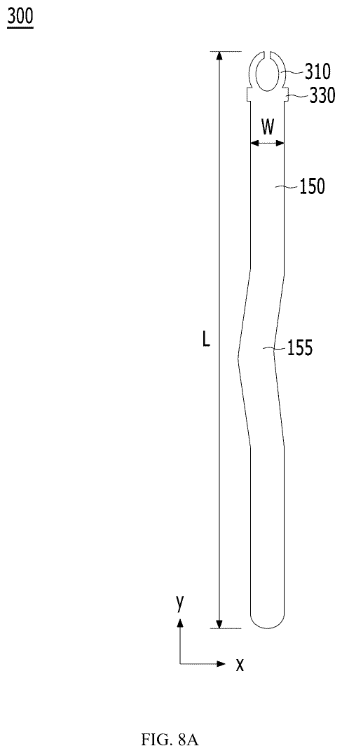

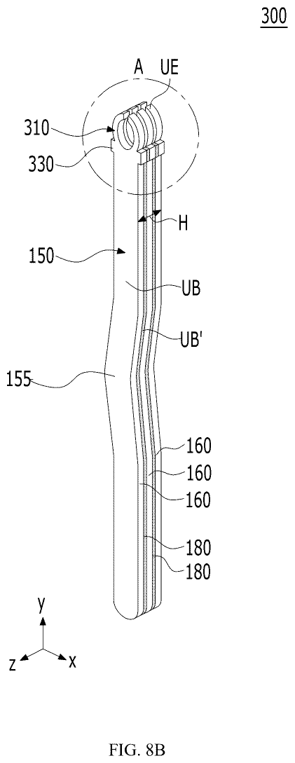

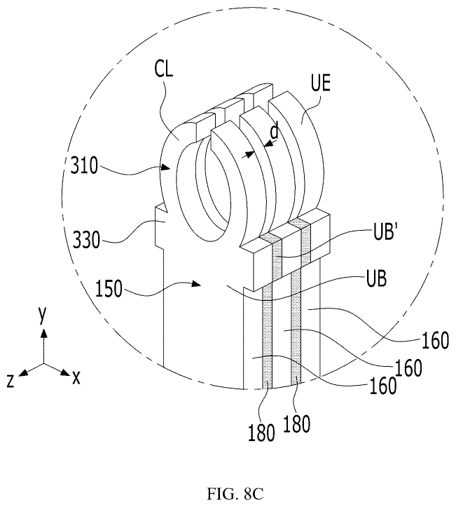

Hereinafter, the electrically conductive contact pin 300 according to the preferred third embodiment of the present invention will be described with reference to FIGS. 8A to 8C. FIGS. 8A to 8C are views illustrating the electrically conductive contact pin 300 according to the preferred third embodiment of the present invention.

The electrically conductive contact pin 300 according to the third embodiment differs from the configuration of the electrically conductive contact pin 100 according to the first embodiment, which comprises a plurality of unit elastic bodies UE formed of closed-type elastic bodies at one end, in that the one end comprises an elastic portion 310 composed of a plurality of unit elastic bodies UE formed of open-type elastic bodies.

The unit elastic body UE formed of an open-type elastic body comprises an internal space but has an upper portion cut to provide at least two contact portions.

The elastic portion 310 is composed of a plurality of unit elastic bodies UE formed of open-type elastic bodies provided at a spacing distance d and is provided on top of the body portion 150 with a catching jaw 330 in between.

The unit elastic body UE formed of an open-type elastic body comprises an internal space penetrating in the thickness direction (±z direction) and a pillar portion CL partially surrounding the internal space with an upper or side portion cut, and has two elastic deformation portions with an arc-shaped cross-section on both sides based on the width direction (±x direction). By comprising a unit elastic body UE formed of an open-type elastic body with two elastic deformation portions, the electrically conductive contact pin 300 according to the third embodiment can form at least two contact portions to improve connection reliability.

### Fourth Embodiment

Next, the fourth embodiment according to the present invention will be described. However, the embodiments described below will focus on characteristic components compared to the first embodiment, and descriptions of components identical or similar to those in the first embodiment will be omitted as much as possible.

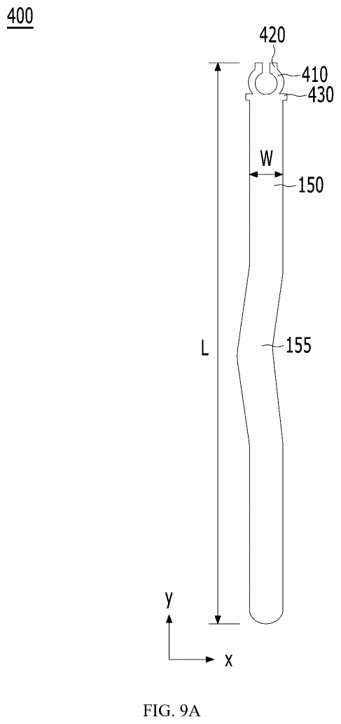

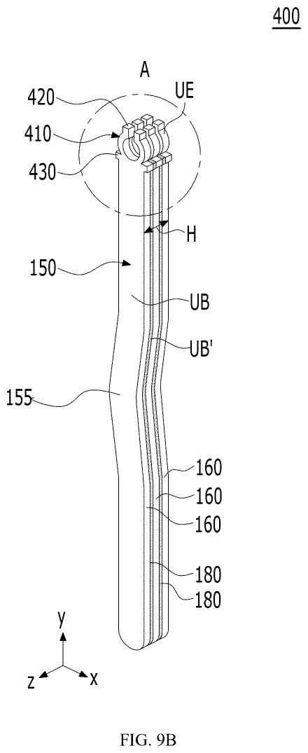

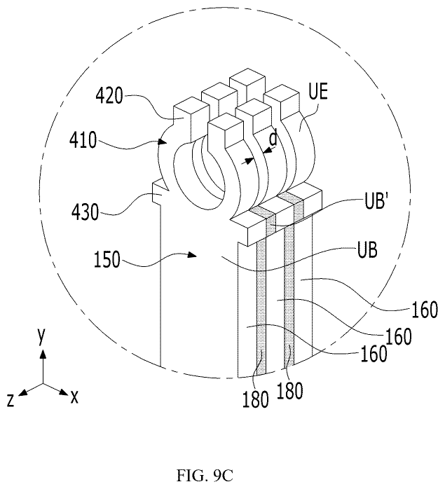

Hereinafter, the electrically conductive contact pin 400 according to the preferred fourth embodiment of the present invention will be described with reference to FIGS. 9A to 9C. FIGS. 9A to 9C are views illustrating the electrically conductive contact pin 400 according to the fourth embodiment of the present invention.

The electrically conductive contact pin 400 according to the preferred fourth embodiment of the present invention differs from the configuration of the electrically conductive contact pin 400 according to the first embodiment, which comprises a plurality of unit elastic bodies UE formed of closed-type elastic bodies and does not include a contact plane portion 420, in that the one end comprises an elastic portion 410 composed of a plurality of unit elastic bodies UE formed of open-type elastic bodies and a contact plane portion 420 configured as a plane on top of each unit elastic body UE.

The unit elastic body UE formed of an open-type elastic body comprises an internal space but has an upper portion cut to provide at least two contact portions.

The unit elastic body UE formed of an open-type elastic body comprises two elastic deformation portions with an arc shape on both sides based on the width direction (±x direction). A contact plane portion 420 is provided on top of each elastic deformation portion. Through this, the electrically conductive contact pin 400 according to the fourth embodiment can improve connection reliability with the connection object.

The elastic portion 410 composed of a plurality of unit elastic bodies UE formed of open-type elastic bodies is provided on top of the body portion 150 with a catching jaw 430 in between.

### Fifth Embodiment

Next, the fifth embodiment according to the present invention will be described. However, the embodiments described below will focus on characteristic components compared to the first embodiment, and descriptions of components identical or similar to those in the first embodiment will be omitted as much as possible.

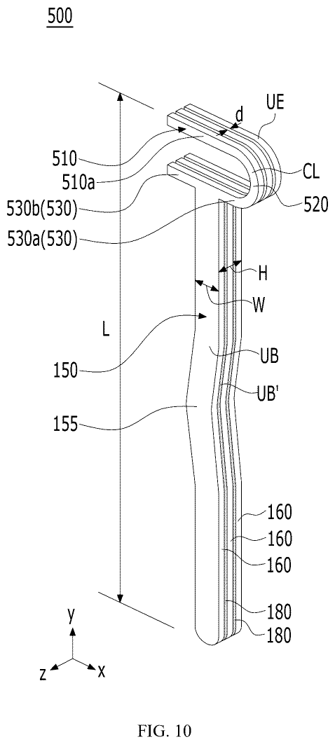

Hereinafter, the electrically conductive contact pin 500 according to the preferred fifth embodiment of the present invention will be described with reference to FIG. 10. FIG. 10 is a view illustrating the electrically conductive contact pin 500 according to the preferred fifth embodiment of the present invention.

The electrically conductive contact pin 500 according to the preferred fifth embodiment of the present invention differs from the configuration of the electrically conductive contact pin 100 according to the first embodiment, which comprises an elastic portion 110a composed of a plurality of unit elastic bodies UE formed of closed-type elastic bodies, in that the elastic portion 510 is composed of a plurality of unit elastic bodies UE formed of open-type elastic bodies.

The open-type elastic body comprises an internal space penetrating in the thickness direction and a pillar portion CL partially surrounding the internal space with a side portion cut.

The electrically conductive contact pin 500 according to the fifth embodiment comprises a plurality of unit elastic bodies UE formed of open-type elastic bodies, including a tip portion 510a at one end that contacts the connection object, a base portion 530 provided on top of the body portion of the electrically conductive contact pin 500, and a connecting portion 520 connecting the tip portion 510a and the base portion 530 to elastically contact the connection object with the tip portion 510a.

The elastic portion 510 composed of a plurality of unit elastic bodies UE formed of open-type elastic bodies provided at a spacing distance d is provided on top of the body portion 150 with a catching jaw 530 in between.

The tip portion 510a is configured as a plane to improve the reliability of contact with the connection object.

The connecting portion 520 is configured to elastically deform when the connection object presses the tip portion 510 and may preferably be provided in an arc shape with curvature. The connecting portion 520 can serve as a pillar portion CL partially surrounding the internal space.

The base portion 530 comprises a first base portion 530a directly connected to the connecting portion 520 and a second base portion 530b located on the opposite side of the connecting portion 520 and not directly connected to the connecting portion 520. The first base portion 530a is connected to the connecting portion 520 and supports the connecting portion 520 and may be configured as a plane. The first base portion 530a is configured to protrude to the right of the body portion 150 of the electrically conductive contact pin 500, and the second base portion 530b is configured to protrude to the left of the body portion 150 of the electrically conductive contact pin 500. Accordingly, the lower surfaces of the first base portion 530a and the second base portion 530b are supported on the upper surface of the upper guide plate GP1. Through this, the electrically conductive contact pin 500 is supported on the upper guide plate GP1 and does not fall out of the upper guide plate GP1.

The unit elastic body UE provided at one end of the electrically conductive contact pin 500 according to the fifth embodiment is configured in a form having a pillar portion CL partially surrounding the internal space with one side open based on the width direction (±x direction) by the tip portion 510a, the connecting portion 520, and the base portion 530. Accordingly, the tip portion 510a, the connecting portion 520, and the base portion 530 are composed of the first metal layer 160 constituting the unit elastic body UE.

### Sixth Embodiment

Next, the sixth embodiment according to the present invention will be described. However, the embodiments described below will focus on characteristic components compared to the first embodiment, and descriptions of components identical or similar to those in the first embodiment will be omitted as much as possible.

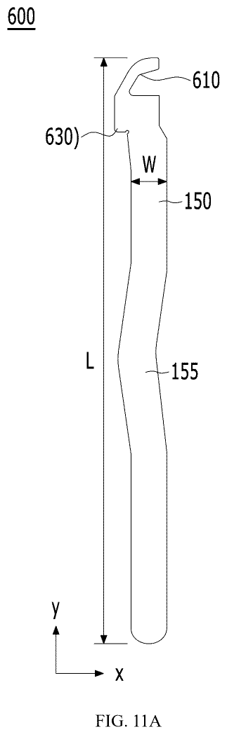

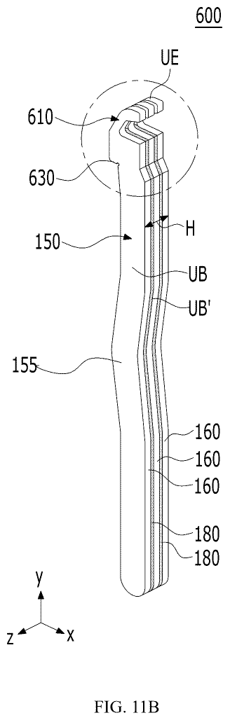

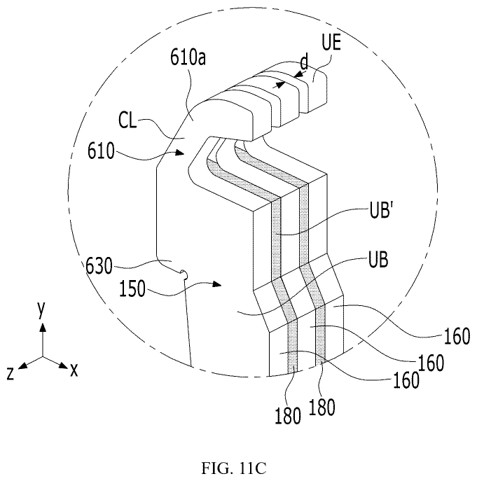

Hereinafter, the electrically conductive contact pin 600 according to the preferred sixth embodiment of the present invention will be described with reference to FIGS. 11A to 11C. FIGS. 11A to 11C are views illustrating the electrically conductive contact pin 600 according to the preferred sixth embodiment of the present invention.

The electrically conductive contact pin 600 according to the preferred sixth embodiment of the present invention differs from the configuration of the electrically conductive contact pin 100 according to the first embodiment, which comprises an elastic portion 110a composed of a plurality of unit elastic bodies UE formed of closed-type elastic bodies at one end, in that the one end comprises an elastic portion 610 composed of a plurality of unit elastic bodies UE formed of open-type elastic bodies.

The open-type elastic body comprises an internal space penetrating in the thickness direction and a pillar portion CL partially surrounding the internal space with a side portion cut.

The electrically conductive contact pin 600 according to the sixth embodiment comprises a plurality of unit elastic bodies UE formed of open-type elastic bodies, including a base portion 630 provided on top of the body portion 150 and a cantilever beam 610a with one end connected to the base portion 630 and the other end configured as a free end, partially surrounding the internal space with a pillar portion CL.

The plurality of unit elastic bodies UE provided at a spacing distance d constitute the elastic portion 610.

The base portion 630 includes a portion protruding from one side of the body portion 150 and is supported on the upper surface of the upper guide plate GP1, performing the function of a catching jaw to prevent the electrically conductive contact pin 600 from falling out of the upper guide plate GP1.

The cantilever beam 610a is a structure that elastically deforms when in contact with the connection object and is configured with one end connected to the base portion 630 on one side of the base portion 630 in the length direction (±y direction) and the other end extending toward the opposite side of the base portion 630.

The base portion 630 is provided between the body portion 150 and the cantilever beam 610a with the same structure as the structure of alternately stacking the first and second metal layers 160, 180 in the thickness direction (±z direction). Accordingly, the base portion 630 is composed of the first and second metal layers 160, 180 of the same material as the first and second metal layers 160, 180 of the body portion 150.

Meanwhile, the cantilever beam 610a is composed of the first metal layer 160 to form the unit elastic body UE.

The body portion 150, the base portion 630, and the unit elastic body UE are continuously connected in the length direction (±y direction) and integrally provided, and the unit elastic body UE is provided by a portion extending in the length direction (±y direction) of the first metal layer 160 constituting the body portion 150 and the base portion 630.

### Manufacturing Method

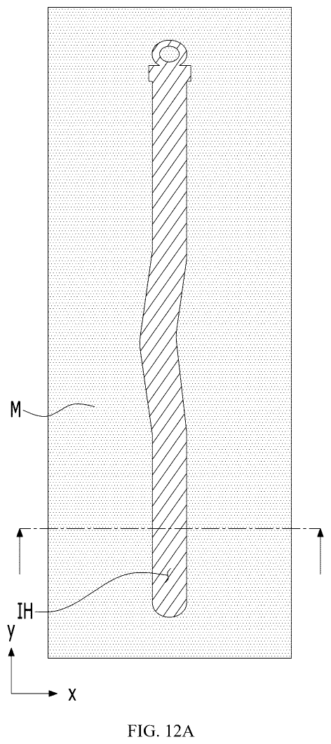

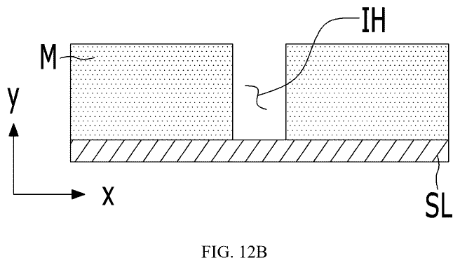

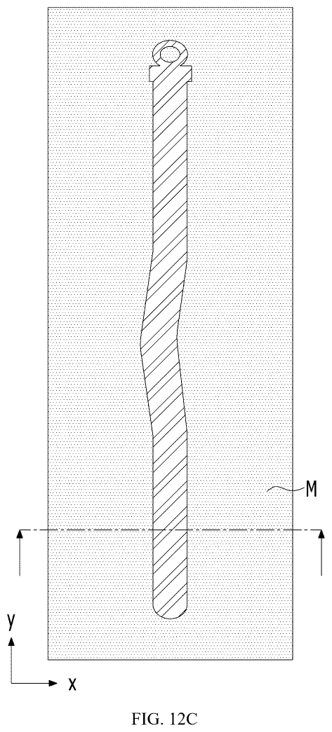

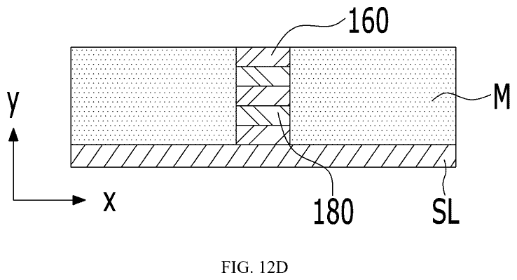

Hereinafter, the manufacturing method of the electrically conductive contact pins 100, 200, 300, 400, 500, 600 according to the preferred embodiments of the present invention will be described with reference to FIGS. 12A to 12D. However, the electrically conductive contact pin 100 illustrated in FIGS. 12A to 12D is an example of the electrically conductive contact pin 100 according to the first embodiment, and the electrically conductive contact pins 200, 300, 400, 500, 600 according to other embodiments are also manufactured by the same manufacturing method described below.

The manufacturing method of the electrically conductive contact pin 100 according to the preferred embodiment of the present invention will be described with reference to FIGS. 12A to 12D.

FIG. 12A is a plan view of a mold M with an etching space IH formed, and FIG. 12B is a cross-sectional view along the cutting line of FIG. 12A. The mold M may be composed of anodized film, photoresist, silicon wafer, or similar materials. However, the mold M according to the more preferred embodiment of the present invention may be composed of anodized film material. Accordingly, the electrically conductive contact pin 100 according to the preferred embodiment of the present invention has effects not only due to the structural advantages but also due to being manufactured using a mold M made of anodized film material. Hereinafter, the mold M made of anodized film material will be described as the preferred mold M.

The anodized film refers to a film formed by anodizing a base metal, and pores refer to holes formed during the process of forming the anodized film by anodizing the base metal. For example, when the base metal is aluminum (Al) or an aluminum alloy, anodizing the base metal forms an anodized film made of aluminum oxide (Al2O3) material on the surface of the base metal. However, the base metal is not limited to this and may include Ta, Nb, Ti, Zr, Hf, Zn, W, Sb, or alloys thereof. The anodized film formed as described above is divided into a barrier layer without vertically formed pores and a porous layer with vertically formed pores. When the base metal with an anodized film having a barrier layer and a porous layer on its surface is removed, only the anodized film made of aluminum oxide (Al2O3) material remains. The anodized film may be formed in a structure where the barrier layer formed during anodizing is removed, and the pores penetrate vertically, or in a structure where the barrier layer formed during anodizing remains, sealing one end of the pores.

The anodized film has a thermal expansion coefficient of 2˜3 ppm/° C. As a result, it undergoes minimal thermal deformation when exposed to high-temperature environments. Therefore, even in high-temperature environments during the manufacturing process of the electrically conductive contact pin 100, precise electrically conductive contact pins 100 can be manufactured without thermal deformation.

The electrically conductive contact pin 100 according to the preferred embodiment of the present invention is manufactured using a mold M made of anodized film material instead of a mold M made of photoresist material, thereby achieving the effects of precision in shape and implementation of fine shapes, which were limited with molds M made of photoresist material. Additionally, while molds M made of photoresist material can produce electrically conductive contact pins with a thickness of about 40 μm, using molds M made of anodized film material allows the production of electrically conductive contact pins 100 with a thickness of 40 μm to 200 μm.

A seed layer SL is provided on the lower surface of the mold M. The seed layer SL may be provided on the lower surface of the mold M before forming the etching space IH in the mold M. Meanwhile, a support substrate (not shown) may be formed below the mold M to improve the handling of the mold M. In this case, the seed layer SL may be formed on the upper surface of the support substrate, and the mold M with the etching space IH formed may be bonded to the support substrate for use. The seed layer SL may be formed of copper (Cu) material and may be formed by a deposition method.

The etching space IH may be formed by wet etching a part of the mold M made of an anodized film material. To achieve this, a photoresist is provided on the upper surface of the mold M, patterned, and then the anodized film in the patterned and opened area reacts with the etching solution to form the etching space IH.

Subsequently, an electroplating process is performed in the etching space IH of the mold M to form the electrically conductive contact pin 100. FIG. 12C is a plan view showing the performance of the electroplating process in the etching space IH, and FIG. 12D is a cross-sectional view along the cutting line of FIG. 12C.

Since the metal layer is formed while growing in the thickness direction of the mold M, the shape of each cross-section in the thickness direction of the electrically conductive contact pin 100 is identical. Furthermore, a plurality of metal layers are alternately stacked in the thickness direction of the electrically conductive contact pin 100. The plurality of metal layers include the first metal layer 160 and the second metal layer 180. The first metal layer 160 is a metal with relatively higher wear resistance than the second metal layer 180, and preferably, it may be formed of a metal selected from rhodium (Rd), platinum (Pt), iridium (Ir), palladium (Pd), nickel (Ni), manganese (Mn), tungsten (W), phosphorus (Ph) or their alloys, or palladium-cobalt (PdCo) alloy, palladium-nickel (PdNi) alloy, nickel-phosphorus (NiPh) alloy, nickel-manganese (NiMn), nickel-cobalt (NiCo), or nickel-tungsten (NiW) alloy. The second metal layer 180 is a metal with relatively higher electrical conductivity than the first metal layer 160, and preferably, it may be formed of a metal selected from copper (Cu), silver (Ag), gold (Au), or their alloys.

The first metal layer 160 is provided on the lower and upper surfaces in the thickness direction of the electrically conductive contact pin 100, and the second metal layer 180 is provided between the first metal layers 160. For example, the electrically conductive contact pin 100 is alternately stacked in the order of the first metal layer 160, the second metal layer 180, and the first metal layer 160, and the number of stacked layers may be three or more.

Meanwhile, after the electroplating process is completed, the metal layers formed by the electroplating process may be densified by applying pressure after heating to a high temperature, thereby making the first metal layer 160 and the second metal layer 180 denser.

When a photoresist material is used as the mold M, the process of applying pressure after heating to a high temperature cannot be performed because the photoresist remains around the metal layers after the electroplating process is completed. In contrast, according to a preferred embodiment of the present invention, since the mold M made of an anodized film material is provided around the metal layers formed by the electroplating process, it is possible to densify the first metal layer 160 and the second metal layer 180 while minimizing deformation due to the low thermal expansion coefficient of the anodized film even when heated to a high temperature. Therefore, compared to the technique using a photoresist as the mold M, it is possible to obtain the first metal layer 160 and the second metal layer 180 with higher density in the body portion 150.

After the electroplating process is completed, a process of removing the mold M and the seed layer SL is performed. When the mold M is made of an anodized film material, the mold M is removed using a solution that selectively reacts with the anodized film material. Additionally, when the seed layer SL is made of copper (Cu), the seed layer SL is removed using a solution that selectively reacts with copper (Cu).

The electrically conductive contact pin 100 removes a part of the second metal layer 180 located at one end of the electrically conductive contact pin 100 using an etchant solution that reacts only with the second metal layer 180. As a result, only a part of the first metal layer 160 is provided at one end of the electrically conductive contact pin 100, forming a plurality of unit elastic bodies UE composed of the first metal layer 160 and spaced apart from each other.

A plating process is performed on a part of the first metal layer 160 located at one end of the electrically conductive contact pin 100. Accordingly, a surface metal is formed on the surface of the first metal layer 160 located at one end of the electrically conductive contact pin 100.

According to the technique of manufacturing pins by electroplating using a photoresist as the mold M, it is difficult to sufficiently increase the height of the mold M with a single layer of photoresist. As a result, the thickness of the electrically conductive contact pin 100 cannot be made sufficiently thick. Considering electrical conductivity, resilience, and brittle fracture, the electrically conductive contact pin 100 needs to be manufactured with a predetermined thickness or more. To increase the thickness of the electrically conductive contact pin 100, a mold M with a multi-layered photoresist may be used. However, in this case, the photoresist of each layer forms slight steps, making it impossible to form the side surface of the electrically conductive contact pin 100 vertically. Additionally, this results in the problem of leaving slight stepped areas.

Furthermore, when the photoresist is multi-layered, it becomes difficult to precisely reproduce the shape of the electrically conductive contact pin 100 with a dimensional range of several to several tens of micrometers or less. Particularly, when the width of the photoresist provided between the internal spaces of the mold M made of photoresist material is 15 micrometers or less, the photoresist is not properly formed, and especially when the height is significantly larger than the width, the photoresist at that position cannot maintain its upright state properly.

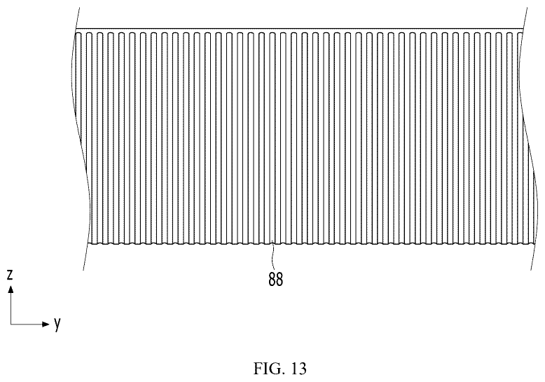

Referring to FIG. 13, the electrically conductive contact pin 100 according to the preferred first embodiment of the present invention includes a fine trench 88 formed on its side surface. On the side surface of the electrically conductive contact pin 100, fine trenches 88 with peaks and valleys having a depth of 20 nanometers or more and 1 micrometer or less are formed in a wrinkled shape, repeating in a direction perpendicular to the thickness direction of the electrically conductive contact pin 100.

The fine trench 88 is formed to extend longitudinally in the thickness direction (±z direction) of the electrically conductive contact pin 100 from its side surface. In other words, the extension direction of the peaks and valleys of the fine trench 88 is the thickness direction (±z direction) of the electrically conductive contact pin 100. Here, the thickness direction (±z direction) of the electrically conductive contact pin 100 refers to the direction in which the metal filler grows during electroplating.

On the side surface of the plate-shaped plate constituting the electrically conductive contact pin 100, the fine trench 88 is configured in a wrinkled shape with peaks and valleys repeating in a direction perpendicular to the thickness direction (±z direction) of the plate-shaped plate.

The fine trench 88 has a depth in the range of 20 nanometers or more and 1 micrometer or less, and its width also falls within the range of 20 nanometers or more and 1 micrometer or less. Here, since the fine trench 88 is caused by the pores formed during the manufacturing of the anodized film mold M, the width and depth of the fine trench 88 have values within the range of the pore diameter of the anodized film mold M. Meanwhile, during the process of forming the etching space UH in the anodized film mold M, some of the pores of the anodized film mold M may be crushed by the etching solution, forming fine trenches 88 with a depth larger than the range of the pore diameter formed during anodization, at least in part.

The anodized film mold M includes numerous pores. The electrically conductive contact pin 100 is manufactured by forming the etching space IH by etching at least a part of the anodized film mold M and performing an electroplating process inside the etching space UH. Accordingly, fine trenches 88 formed in contact with the pores of the anodized film mold M are provided on the side surface of the electrically conductive contact pin 100.

Since the fine trench 88 has a wrinkled shape with peaks and valleys repeating in a direction perpendicular to the thickness direction and a depth of 20 nanometers or more and 1 micrometer or less, it has the effect of increasing the surface area on the side surface of the electrically conductive contact pin 100. Through the configuration of the fine trench 88 formed on the side surface of the electrically conductive contact pin 100, the surface area through which current flows is increased due to the coating effect, thereby increasing the current density flowing through the electrically conductive contact pin 100 and improving the electrical characteristics (particularly, high-frequency characteristics) of the electrically conductive contact pin 100. Additionally, through the configuration of the fine trench 88, heat generated in the electrically conductive contact pin 100 can be quickly dissipated, thereby suppressing the temperature rise of the electrically conductive contact pin 100.

As described above, although the preferred embodiments of the present invention have been described with reference to the above, those skilled in the art can variously modify or change the present invention within the scope and spirit of the present invention as set forth in the following claims.

What is claimed is:

1. An electrically conductive contact pin having one end contacting a connection pad of an inspection apparatus and another end contacting a connection pad of an inspection object to inspect the inspection object, comprising:
a body portion comprising a first metal layer and a second metal layer made of a metal having relatively higher electrical conductivity than the first metal layer, alternately stacked in a thickness direction; and
an elastic portion provided at the one end to enable the one end to be pressed and compressed by the connection pad of the inspection apparatus when a guide plate is installed on the inspection apparatus side, thereby maintaining the one end in constant contact with the connection pad of the inspection apparatus,
wherein the elastic portion comprises a plurality of unit elastic bodies spaced apart from each other in the thickness direction.

2. The electrically conductive contact pin of claim 1,
wherein the one end comprises a closed-type elastic body having an internal space.

3. The electrically conductive contact pin of claim 1,
wherein the one end comprises a closed-type unit elastic body having an internal space and a contact plane portion configured as a plane on top of the closed-type unit elastic body.

4. The electrically conductive contact pin of claim 1,
wherein the one end comprises the unit elastic body having an internal space with an upper portion cut to provide at least two contact portions.

5. The electrically conductive contact pin of claim 1,
wherein the one end comprises the unit elastic body having an internal space with an upper portion cut to provide at least two contact portions and a contact plane portion configured as a plane on top of the unit elastic body.

6. The electrically conductive contact pin of claim 1,
wherein the one end comprises the unit elastic body having an internal space with a side portion cut.

7. The electrically conductive contact pin of claim 1,
wherein the one end comprises a catching jaw formed larger than a size of the guide hole to prevent the unit elastic body from passing through the guide hole of the guide plate,
wherein the unit elastic body is positioned above the catching jaw.
